(19) United States
(12) Patent Application Publication
(10) Pub. No.: US 2026/0197921 A1
(43) Pub. Date: Jul. 9, 2026

(54) LIGHTING COMPONENT, LIGHTING FIXTURE AND LAMP

(71) Applicant: CHAO LI, SHENZHEN (CN)

(72) Inventor: CHAO LI, SHENZHEN (CN)

(21) Appl. No.: 19/555,869

(22) Filed: Mar. 3, 2026

(30) Foreign Application Priority Data
Feb. 11, 2026 (CN) 202620208908.X

(51) Int. Cl. H05B 47/155; H05B 45/10; H05B 45/325; H05B 47/16; H05B 47/195; H10H 29/85; H10H 29/852

(52) U.S. Cl. CPC H05B 47/155; H05B 45/10; H05B 45/325; H05B 47/16; H05B 47/195; H10H 29/852; H10H 29/857

(57) ABSTRACT

A lighting component is provided, which includes: a first LED chip and a second LED chip for generating stable and/or variable light when energized; a control MCU connected to both LED chips, which controls the light emitted by the first LED chip and/or the second LED chip via pulse signals when energized; at least one positive lead and at least one negative lead, wherein the positive lead connects to the input pin of the LED chip and/or the positive terminal of the control MCU, and the negative lead connects to the output pin of the LED chip and/or the negative terminal of the control MCU.

### CROSS REFERENCE TO RELATED APPLICATIONS

This application claims foreign priority of Chinese Patent Application No. 202620208908. X, filed on Feb. 11, 2026 in the China National Intellectual Property Administration, the disclosures of all of which are hereby incorporated by reference.

### FIELD

The present disclosure relates to the technical field of lighting devices, specifically to lighting component, lighting fixture, and lamp.

### BACKGROUND

With the continuous development of the economy and society and the steady improvement in living standards, people's material and spiritual needs are growing, placing higher demands on the functionality of everyday items. Take lighting fixtures as an example. Whether in formal settings or home leisure environments, lighting is often used to create specific atmospheres-such as dynamic effects like brightness transitions, flickering, or alternating light and shadow. These features are commonly found in products like mood lamps, aromatherapy lamps, candle lamps, and firefly lamps. Their core functions illumination to encompass emotional expression and scene enhancement.

Among currently known technical solutions, light-emitting components of such lamps mostly utilize LED chips, achieving dimming through methods such as adjusting the drive current or employing pulse width modulation (PWM). Although these dimming technologies have been widely adopted across various lighting fixtures, they still exhibit notable shortcomings: First, to achieve luminous efficacy control, fixtures often require integrating numerous electronic and structural components, resulting in complex overall designs. Second, dimming functionality typically necessitates installing dedicated driver units, which not only increases system complexity but also complicates installation and usage, thereby compromising user experience.

Additionally, in certain specific applications, users expect lighting fixtures to highly simulate the visual effects of real flames to enhance the immersive and realistic feel of the environment. However, existing lighting solutions remain rudimentary in flame simulation, with significant gaps between their light effects and actual flames. Real flames possess a three-dimensional layered structure, typically composed of an inner flame and an outer flame, forming a near-spherical shape. The inner flame remains relatively stable, while the outer flame dynamically fluctuates. Currently, most lighting fixtures use a single LED chip to simulate flames, achieving only simple dynamic dimming effects. This approach fails to reproduce the layered depth and three-dimensional dynamic characteristics of real flames. A few multi-LED solutions attempt to mimic flame shapes but generally suffer from complex structures, high costs, and unreliability, making them impractical for mass-market products.

In summary, existing technologies primarily face these issues:
1. Complex dimming systems: Most dimmable fixtures rely on multiple components and dedicated drivers, resulting in cumbersome structures that are inconvenient to install and use;
2. Subpar flame simulation: Single-LED solutions fail to convey flame's three-dimensional depth and dynamic movement, resulting in rigid lighting effects and poor realism;
3. High cost and low reliability: Multi-LED solutions, while attempting to enhance simulation, introduce bulkiness, elevated costs, and increased failure rates, hindering product adoption.

### SUMMARY

The present disclosure provides lighting component, lighting fixture, and lamp to overcome the limitations of current models.

According to some embodiments of the present disclosure, a lighting component is provided, including: a first LED chip and a second LED chip for generating stable and/or variable light when energized; a control MCU connected to both LED chips, which controls the light emitted by the first LED chip and/or the second LED chip via pulse signals when energized; at least one positive lead and at least one negative lead, wherein the positive lead connects to the input pin of the LED chip and/or the positive terminal of the control MCU, and the negative lead connects to the output pin of the LED chip and/or the negative terminal of the control MCU.

Furthermore, the control MCU and at least one of the LED chips are encapsulated within the same electronic encapsulation material, with portions of the positive lead and the negative lead extending outside the electronic encapsulation material.

Furthermore, the electronic encapsulation material has a top surface and a bottom surface, with one LED chip positioned near the top surface and another LED chip positioned near the bottom surface.

Furthermore, the electronic encapsulation material is epoxy resin.

Furthermore, the control MCU is connected to the first LED chip via an input/output pin and is capable of outputting varying level signals to the first LED chip upon powering the control MCU to control its light emission.

According to some embodiments of the present disclosure, a lighting fixture is provided, including the lighting component described above, further comprising a driver board, which controls the light emitted by the second LED chip and communicates with the control MCU; wherein the positive lead and negative lead are both connected to the driver board; the driver board has a positive terminal and a negative terminal, for connecting to the positive and negative terminals of the power supply respectively.

Furthermore, the driver board comprises a driver MCU, with the positive terminal pin of the driver MCU connected to the positive terminal of the driver board, and the negative terminal pin of the driver MCU connected to the negative terminal of the driver board; the driver MCU is connected to the output pin of the second LED chip via an input/output pin, enabling the driver MCU to output varying level signals to the second LED chip upon powering on to control its light emission, and to transmit commands to the control MCU to regulate the light emission mode of the first LED chip.

Furthermore, the driver MCU has a crystal oscillator input pin and a crystal oscillator output pin, and the crystal oscillator input pin and output pin are connected to a crystal oscillator module for timing.

Furthermore, the driver MCU is connected via input/output pins to an infrared module; upon receiving an infrared signal, the infrared module transmits an electrical signal to the input/output pins of the driver MCU to alter the timing mode within the driver MCU and/or the control waveform output by the driver MCU.

According to some embodiments of the present disclosure, a lamp is provided, including the lighting component described above, further comprising a diffuser lampshade and/or a housing.

### BRIEF DESCRIPTION OF THE DRAWINGS

The accompanying drawings are provided to facilitate further understanding of the present disclosure and form part of the present disclosure. The illustrative embodiments and their descriptions are intended to explain the present disclosure and do not constitute undue limitations thereof. In the drawings:

FIG. 1 shows the pinout diagram of the NY8A054D8 microcontroller according to various embodiments;

FIG. 2 shows the structural schematic diagram of the lighting component according to embodiment 1;

FIG. 3 shows the structural schematic diagram of the lighting component according to embodiment 2;

FIG. 4 shows the structural schematic diagram of the lighting component according to embodiment 3;

FIG. 5 shows the structural schematic diagram of the lighting component according to embodiment 4;

FIG. 6 shows the structural schematic diagram of the lighting component according to embodiment 5;

FIG. 7 is a logical connection diagram of the lighting fixture according to embodiment 6;

FIG. 8 is a structural schematic diagram of the lighting fixture according to embodiment 6.

### REFERENCE SIGNS

100. Lighting component; 1. LED chip; 1a. First LED chip; 1b. Second LED chip; 2. Control MCU; 21. First PWM pin; 3. Positive lead; 4. Negative lead; 5. Electronic encapsulation material; 200. Lighting fixture; 6. Driver board; 61. First voltage-regulating capacitor; 62. Fourth voltage-regulating capacitor; 63. Voltage-dividing resistor; 7. Driver MCU; 71. Second PWM pin; 72. Clock pin; 73. Crystal oscillator input pin; 74. Crystal oscillator output pin; 8. Crystal oscillator module; 81. Crystal oscillator; 82. Second load capacitor; 83. Third load capacitor; 9. Infrared module; 91. Infrared receiver; 911. Output terminal; 92. Fifth voltage-regulating capacitor.

### DETAILED DESCRIPTION

To further illustrate the content, features, and efficacy of the present disclosure, the following embodiments are provided and described in detail with reference to the accompanying drawings:

### Embodiment 1

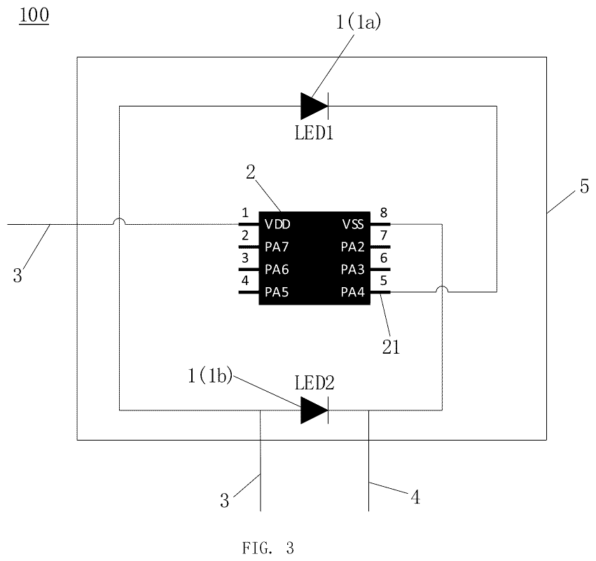

Referring to FIG. 2, this embodiment discloses a lighting component 100 including two LED chips 1, namely a first LED chip 1a and a second LED chip 1b, further including a control MCU 2, a positive lead 3, and a negative lead 4. The LED chips 1 feature input pins and output pins capable of emitting light when energized. The control MCU 2 features a positive terminal, a negative terminal, and multiple input/output pins including a first PWM pin 21. The positive and negative terminals of the control MCU 2 connect to high and low potential points respectively, while the first PWM pin 21 is electrically connected to the output pin of the first LED chip 1a. The first PWM pin 21 outputs PWM control signals to regulate the light output of the first LED chip 1a. Positive lead 3 and negative lead 4 are both metal conductors or wires used to extend the electrodes. In this embodiment, one positive lead 3 and one negative lead 4 are provided. Positive lead 3 is electrically connected to the input pins of both LED chips 1 and the positive terminal of the control MCU2, while the negative lead 4 is electrically connected to the output pin of the second LED chip 1b and the negative terminal of the control MCU 2.

The control MCU 2 and one or both of the aforementioned two LED chips 1 are encapsulated within the same electronic encapsulation material 5. In this embodiment, the control MCU 2 and the first LED chip 1a are encapsulated within the electronic encapsulation material 5. This electronic encapsulation material 5 employs a light-transmissive material, which may be an organic silicone potting compound, epoxy molding compound, or epoxy resin. In this embodiment, the electronic encapsulation material 5 uses epoxy resin, which possesses excellent light transmittance, heat resistance, and high hardness. The encapsulated electronic encapsulation material 5 possesses a top surface and a bottom surface. The first LED chip 1a is positioned near the top surface of the electronic encapsulation material 5, while the second LED chip 1b is positioned near the bottom surface of the electronic encapsulation material 5. Consequently, during operation, the first LED chip 1a can simulate the outer flame of a flame by emitting varying light, while the second LED chip 1b can simulate the inner flame by emitting stable light. Both the positive lead 3 and negative lead 4 have portions located within the electronic encapsulation material 5, with the remaining portions extending outside the electronic encapsulation material 5.

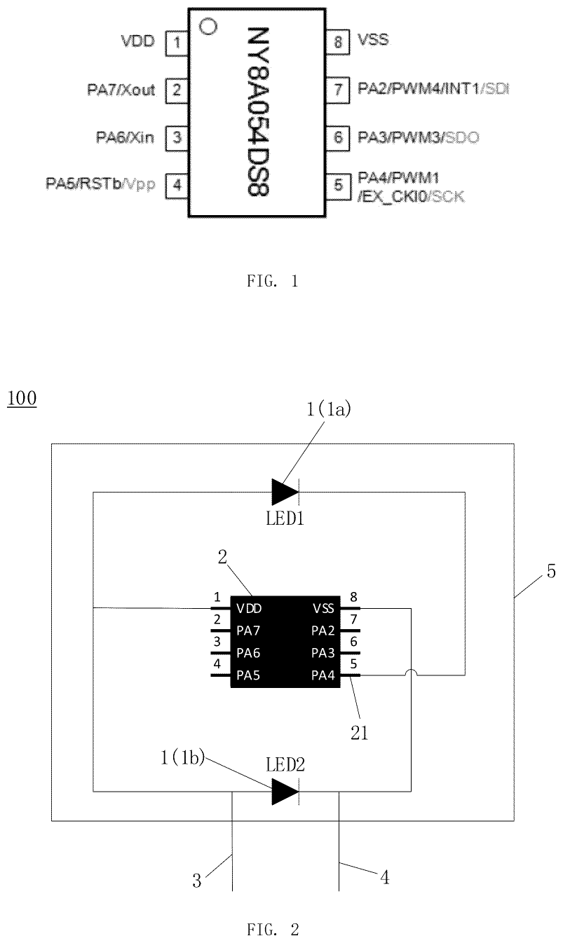

Specifically, with reference to FIGS. 1 and 2, in this embodiment, the control MCU 2 employs the NY8A054D8 microcontroller manufactured by Nyquest Technology Co., Ltd. The technical parameters of this microcontroller constitute prior art readily accessible to those skilled in the art and are not elaborated upon herein. Additionally, this microcontroller features eight pins: VDD, VSS, PA2, PA3, PA4, PA5, PA6, and PA7. The correspondence between pins and functions is shown in Table 1. In this embodiment, the positive terminal pin of the control MCU 2 is the VDD pin, the negative terminal pin is the VSS pin, and the first PWM pin 21 is the PA4 pin. In this embodiment, the positive lead 3 is electrically connected to the input pins of both LED chips 1 and the VDD pin of the control MCU 2. The negative lead 4 is electrically connected to the output pin of the second LED chip 1b and the VSS pin of the control MCU 2. The output pin of the first LED chip 1a is electrically connected to the PA4 pin of the control MCU 2.

TABLE 1
NY8A054D8 Microcontroller Pin Description

| Pin | | | |
|---|---|---|---|
| Number | Pin Name | I/O | Description |
| 1 | PA2/PWM4/INT1/SDI | I/O | PA2 is a bidirectional I/O pin that can |
| | | | also function as a comparator input pin. |
| | | | PA2 can output PWM4. |
| | | | PA2 is the input pin INT1 for External |
| | | | Interrupt 1. |
| | | | PA2 also serves as the programming data |
| | | | input SDI. |
| 2 | PA3/PWM3/SDO | I/O | PA3 is a bidirectional I/O pin that can |
| | | | also function as a comparator input pin. |
| | | | PA3 can output PWM3. |
| | | | PA3 also serves as the programming data |
| | | | output (SDO). |
| 3 | PA4/PWM1/EX_CKIO/SCK | I/O | PA4 is a bidirectional I/O pin. |
| | | | PA4 can output PWM1. |
| | | | PA4 can serve as the external clock |
| | | | source EX_CKIO for Timer 0/1. |
| | | | PA4 is also the programming clock input |
| | | | SCK. |
| 4 | PA5/RSTb/Vpp | I/O | PA5 can be selected as an input pin or |
| | | | an open-drain output pin. |
| | | | PA5 can function as the reset pin RSTb. |
| | | | PA5 also serves as the programming high |
| | | | voltage input Vpp. |
| 5 | PA6/Xin | I/O | PA6 is a bidirectional I/O pin. |
| | | | PA6 can function as the crystal |
| | | | oscillator input pin Xin. |
| 6 | PA7/Xout | I/O | PA7 is a bidirectional I/O pin. |
| | | | PA7 can function as the crystal |
| | | | oscillator output pin Xout. |
| | | | PA7 can also serve as the instruction |
| | | | clock output. |
| 1 | VDD | P | Positive terminal of the power supply |
| 8 | VSS | P | Negative terminal of the power supply |

The lighting component 100 in this embodiment integrates both an LED chip 1 and an MCU. Through external signal input, it enables more convenient and straightforward light control. Furthermore, the two LED chips 1 are spatially arranged in an upper-lower configuration, allowing them to respectively simulate the inner and outer flames of a real flame, thereby achieving a more realistic simulation of actual flame effects.

### Embodiment 2

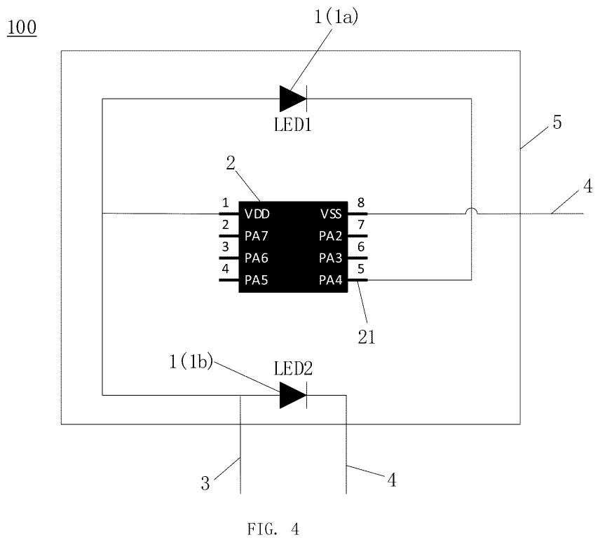

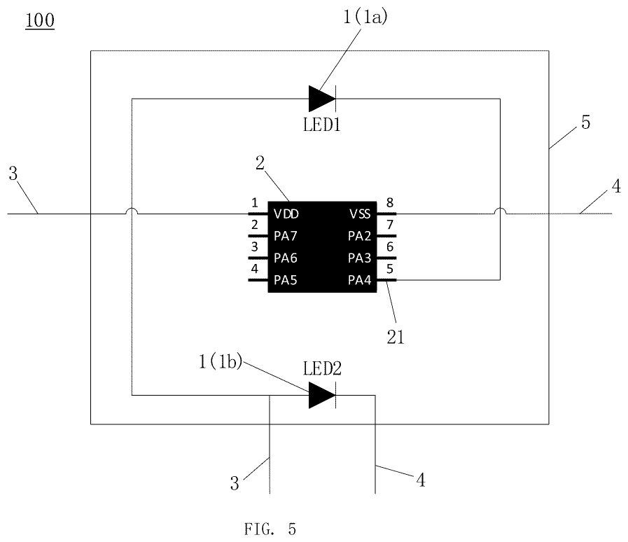

Referring to FIG. 3, this embodiment discloses a lighting component 100. The difference from embodiment 1 lies in the configuration of electrode leads: two positive leads 3 are provided, while one negative lead 4 is provided. The first positive lead 3 is electrically connected to the input pins of both LED chips 1. The second positive lead 3 is electrically connected to the positive pin of the control MCU 2. The negative lead 4 is electrically connected to both the output pin of the second LED chip 1b and the negative terminal pin of the control MCU 2.

### Embodiment 3

Referring t this embodiment discloses a lighting component 100. The difference from embodiment 1 lies in the configuration of electrode leads: this embodiment features one positive lead 3 and two negative leads 4. The positive lead 3 is electrically connected to the input pins of both LED chips 1 and the positive pin of the control MCU 2. The first negative lead 4 is electrically connected to the negative pin of the control MCU 2. The second negative lead 4 is electrically connected to the output pin of the second LED chip 1b.

### Embodiment 4

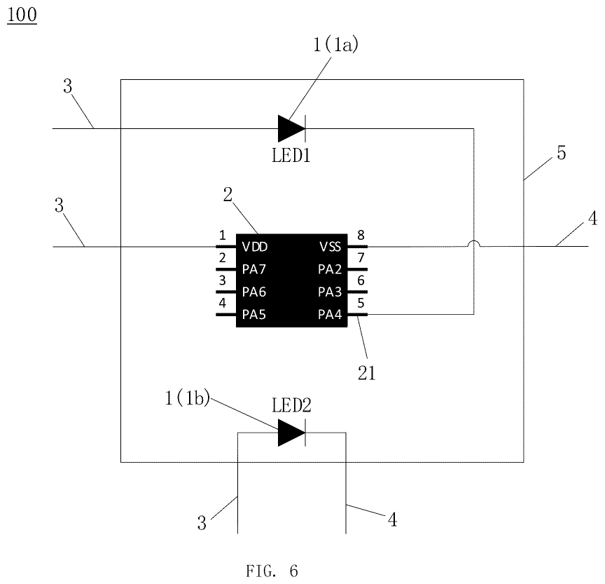

Referring to FIG. 5, this embodiment discloses a lighting component 100. The difference from embodiment 1 lies in the configuration of two positive leads 3 and two negative leads 4. The first positive lead 3 is electrically connected to the input pins of both LED chips 1, while the second positive lead 3 is electrically connected to the positive terminal pin of the control MCU 2. The first negative lead 4 is electrically connected to the negative terminal of the control MCU 2, while the second negative lead 4 is electrically connected to the output pin of the second LED chip 1b.

### Embodiment 5

Referring to FIG. 6, this embodiment discloses a lighting component 100. The difference from embodiment 1 lies in the configuration of three positive leads 3 and two negative leads 4. The first positive lead 3 is electrically connected to the input pin of the first LED chip 1a, the second positive lead 3 is electrically connected to the input pin of the second LED chip 1b, while the third positive lead 3 is electrically connected to the positive pin of the control MCU 2. The first negative lead 4 is electrically connected to the negative pin of the control MCU 2, and the second negative lead 4 is electrically connected to the output pin of the second LED chip 1b.

### Embodiment 6

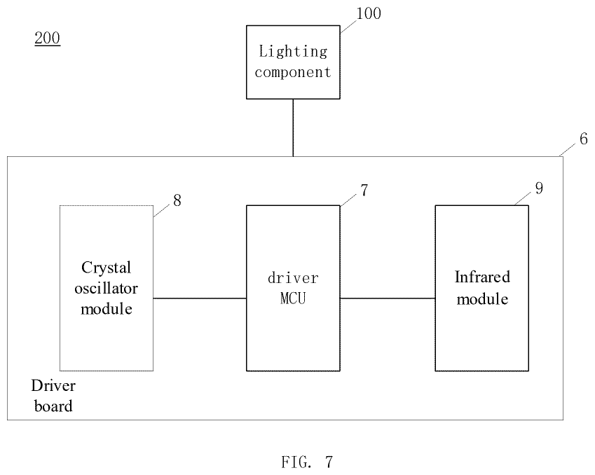

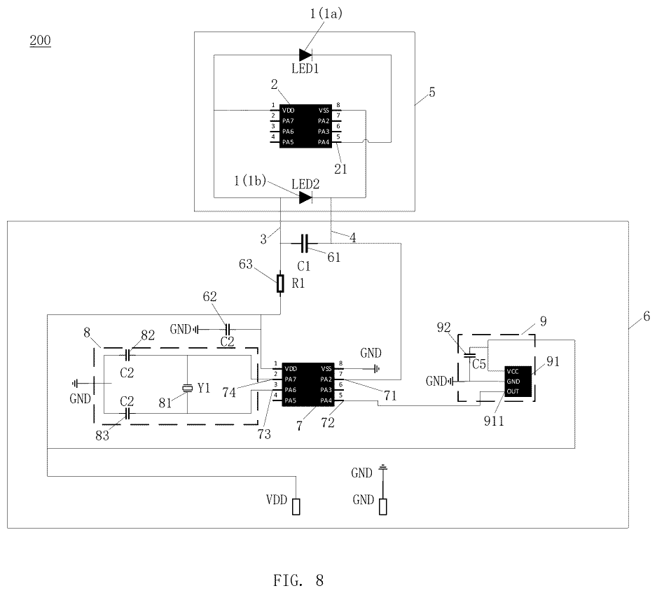

Referring to FIGS. 7 and 8, this embodiment discloses a lighting fixture 200, including the lighting component 100 from embodiment 1, and additionally including a driver board 6. The driver board 6 is a PCB board used for communication with the control MCU 2. Both the positive lead 3 and negative lead 4 of the lighting component 100 are connected to the PCB board. Specifically, the driver board 6 houses a driver MCU 7, a crystal oscillator module 8, and an infrared module 9. Both the crystal oscillator module 8 and the infrared module 9 are electrically connected to the driver MCU 7. The crystal oscillator module 8 provides precise timing to the driver MCU 7, while the infrared module 9 receives infrared signals and transmits electrical signals to the driver MCU 7 as control commands based on the received infrared signals.

The driver board 6 features a positive terminal and a negative terminal, designed for connection to the positive and negative terminals of a power source, respectively. During operation, the positive terminal of the driver board 6 can be connected to the positive terminal of the mains power via a power adapter, or to the positive terminal of a battery. The negative terminal of the driver board 6 can be connected to the negative terminal of the mains power via a power adapter, or to the negative terminal of a battery. The positive lead 3 of the lighting component 100 is electrically connected to the positive terminal of the driver board 6. The driver MCU 7 features a positive terminal pin, a negative terminal pin, and multiple input/output pins, including the second PWM pin 71 and the clock pin 72. The positive terminal pin is electrically connected to the positive terminal of the driver board 6, while the negative terminal pin is electrically connected to the negative terminal of the driver board 6. The second PWM pin 71 is electrically connected to the negative lead 4 of the lighting component 100. This arrangement connects the output pin of the second LED chip 1b to the second PWM pin 71, enabling the second PWM pin 71 to output PWM control signals to the second LED chip 1b. Consequently, the light emitted by the second LED chip 1b can be controlled.

The driver board 6 is equipped with a first voltage-regulating capacitor 61. The two terminals of the first voltage-regulating capacitor 61 are electrically connected between the positive lead 3 and the negative lead 4, respectively. The first voltage-regulating capacitor 61 stabilizes the voltage between the positive lead 3 and the negative lead 4, thereby enhancing the stability of the voltage output from the driver board 6 to the lighting component 100. A fourth voltage-regulating capacitor 62 is also mounted on the driver board 6. The two terminals of the fourth voltage-regulating capacitor 62 are connected between the positive pin of the driver MCU 7 and the negative terminal of the driver board 6, respectively, to stabilize the operating voltage of the driver MCU 7.

The clock pin 72 of the driver MCU 7 serves as the external clock source pin for its internal timer. The infrared module 9 includes an infrared receiver 91, with the positive terminal of the infrared receiver 91 connected to the positive terminal of the driver board 6, while its negative terminal connects to the negative terminal of the driver board 6. A fifth voltage-regulating capacitor 92 bridges the positive and negative terminals of the infrared receiver 91, ensuring its stability during standby operation. The infrared receiver 91 features an output terminal 911 for generating electrical signals. This output terminal 911 is connected to the clock pin 72. Based on infrared signals received by the infrared receiver 91, the output terminal 911 transmits corresponding electrical signals to the driver MCU 7 as control commands. These commands alter the timing mode within the driver MCU 7 and/or the control waveform output by the second PWM pin 71. Therefore, the infrared module 9 allows users to conveniently configure the on/off status, flashing patterns, and brightness levels of the two LED chips 1 via an infrared remote control.

The driver MCU7 also features crystal oscillator input pin 73 and crystal oscillator output pin 74. The aforementioned crystal oscillator module 8 is mounted between crystal oscillator input pin 73 and crystal oscillator output pin 74, providing a high-precision clock frequency to the internal circuitry of the driver MCU7. Specifically, the crystal oscillator module 8 includes a crystal oscillator 81, a second load capacitor 82, and a third load capacitor 83. The crystal oscillator 81 is electrically connected across crystal oscillator input pin 73 and crystal oscillator output pin 74. The second load capacitor 82 and third load capacitor 83 are connected in series, with both ends electrically connected to the two terminals of crystal oscillator 81. The wire between second load capacitor 82 and third load capacitor 83 is connected to the negative terminal of driver board 6. This configuration forms an oscillation circuit between crystal oscillator module 8 and the internal components of driver MCU 7. Upon powering driver MCU 7, this circuit provides a frequency-stable clock signal to driver MCU 7, ensuring the precision of its timing functions.

The first voltage-regulating capacitor 61, second load capacitor 82, third load capacitor 83, fourth voltage-regulating capacitor 62, and fifth voltage-regulating capacitor 2 are all surface-mount capacitors for convenient PCB assembly. Additionally, a voltage-dividing resistor 63 is connected between the positive terminal of the driver MCU 7 on the positive terminal of the driver board 6 and the positive terminal of the first voltage-regulating capacitor 61. The voltage-dividing resistor 63 is mounted on the driver board 6 and is used to set the output voltage provided by the power supply to the lighting component 100.

In this embodiment, the driver MCU7 employs the NY8A054D8 microcontroller manufactured by Nyquest Technology Co., Ltd., which is identical to the control MCU 2. It features eight pins: VDD, VSS, PA2, PA3, PA4, PA5, PA6, and PA7. The correspondence between pins and functions is shown in Table 1. Specifically, the positive terminal pin of the driver MCU 7 in this embodiment is the VDD pin, and the negative terminal pin is the VSS pin. The second PWM pin 71 corresponds to PA2 in this embodiment, and the clock pin 72 corresponds to PA4. The crystal oscillator input pin 73 corresponds to PA6, and the crystal oscillator output pin 74 corresponds to PA7.

In this embodiment, the principle of controlled dimming for the first LED chip 1a and the second LED chip 1b is as follows: Both the first PWM pin 21 of the control MCU 2 and the second PWM pin 71 of the driver MCU 7 can output PWM control signals. These PWM control signals manifest as voltage levels fluctuating over time between the PWM pins and the MCU's positive terminal. A higher voltage corresponds to greater brightness of the LED chip 1, while a lower voltage results in dimmer illumination. The PWM control signal manifests as a sawtooth pattern on a voltage-time graph. A higher proportion of time at maximum voltage (corresponding to a lower voltage duty cycle) results in greater brightness of LED chip 1, while a lower proportion yields dimmer illumination. When the maximum voltage occupies the largest proportion on the voltage-time graph, the graph appears as a straight line. At this point, the voltage duty cycle is at its lowest, and LED chip 1 achieves maximum brightness.

Furthermore, the first PWM pin 21 outputs a PWM control signal with continuously varying duty cycle to the first LED chip 1a according to the preset program within the control MCU 2. Consequently, the brightness of the first LED chip 1a also changes over time, creating a flickering effect. Since the first LED chip 1a is positioned above the second LED chip 1b, when the lighting component 100 in this embodiment simulates candlelight, the first LED chip 1a corresponds to the outer flame portion of the candle, presenting an effect of continuously varying outer flame brightness.

The second PWM pin 71 outputs a PWM control signal with a constant duty cycle to the second LED chip 1b according to the preset program within the driver MCU 7. This maintains the brightness of the second LED chip 1b constant, creating a steady-on effect. Since the second LED chip 1b is positioned beneath the first LED chip 1a, when the lighting component 100 in this embodiment simulates candlelight, the second LED chip 1b corresponds to the inner flame portion of the candle, presenting the effect of a stable and unchanging inner flame brightness.

When it is necessary to change the light emission mode of the first LED chip 1a, the infrared module 9 receives an infrared signal and sends an electrical signal to the clock pin 72 of the driver MCU 7. The driver MCU 7 communicates with the control MCU 2 by transmitting electrical signals based on the different types of electrical signals received at clock pin 72. This causes the control MCU 2 to modify the PWM control waveform output from the first PWM pin 21 according to its internal preset program. This achieves the effects of controlling the on/off state, flashing mode, and luminous intensity of the first LED chip 1a.

Similarly, when it is necessary to change the light emission mode of the second LED chip 1b, the infrared module 9 receives an infrared signal and sends an electrical signal to the clock pin 72 of the driver MCU 7. The driver MCU 7, based on the different types of electrical signals received at the clock pin 72, modifies the PWM control waveform output from the second PWM pin 71 according to its internally preset program. This achieves the effect of controlling the on/off state and brightness of the second LED chip 1b.

In this embodiment, the lighting component 100, in conjunction with the driver board 6 capable of communicating with it, enables convenient and straightforward regulation of the LED chip 1's illumination. This configuration features a simple structure, low cost, and high reliability.

### Embodiment 7

This embodiment discloses a lamp including any one of the lighting components 100 described in Embodiments 1-5, further including a diffuser lampshade. The lighting component 100 is positioned inside the diffuser lampshade, which is preferably constructed as a bulb shell to diffuse light and enhance the light dispersion effect. The lamp of this embodiment also includes an outer housing, with the diffuser lampshade mounted on the outer housing.

The lighting component 100 of the present disclosure integrates both LED chip 1 and MCU. Through external signal input, it enables more convenient and straightforward light control. Furthermore, the two LED chips 1 are spatially arranged in an upper-lower configuration, allowing them to respectively simulate the inner and outer flames of a real flame, thereby achieving a more realistic flame effect. Furthermore, within the lighting fixture 200, the lighting component 100 works in conjunction with a compatible driver board 6 to facilitate straightforward light control. This configuration offers a simple structure, low cost, and high reliability.

The above are merely embodiments of the present disclosure and are not intended to limit the scope of the present disclosure. For those skilled in the art, the present disclosure may be subject to various modifications and variations. Any modifications, equivalent substitutions, improvements, etc., made within the spirit and principles of the present disclosure shall be included within the scope of the appended claims.

What is claimed is:

1. A lighting component comprising:
a first LED chip and a second LED chip for generating stable and/or variable light when energized;
a control MCU connected to both LED chips, which controls the light emitted by the first LED chip and/or the second LED chip via pulse signals when energized;
at least one positive lead and at least one negative lead, wherein the positive lead connects to the input pin of the LED chip and/or the positive terminal of the control MCU, and the negative lead connects to the output pin of the LED chip and/or the negative terminal of the control MCU.

2. The lighting component according to claim 1, wherein the control MCU and at least one of the LED chips are encapsulated within the same electronic encapsulation material, with portions of the positive lead and the negative lead extending outside the electronic encapsulation material.

3. The lighting component according to claim 2, wherein the electronic encapsulation material has a top surface and a bottom surface, with one LED chip positioned near the top surface and another LED chip positioned near the bottom surface.

4. The lighting component according to claim 2, wherein the electronic encapsulation material is epoxy resin.

5. The lighting component according to claim 1, wherein the control MCU is connected to the first LED chip via an input/output pin and is capable of outputting varying level signals to the first LED chip upon powering the control MCU to control its light emission.

6. A lighting fixture, comprising the lighting component described in claim 1, further comprising a driver board, which controls the light emitted by the second LED chip and communicates with the control MCU;
wherein the positive lead and negative lead are both connected to the driver board; the driver board has a positive terminal and a negative terminal, for connecting to the positive and negative terminals of the power supply respectively.

7. The lighting fixture according to claim 6, wherein the driver board comprises a driver MCU, with the positive terminal pin of the driver MCU connected to the positive terminal of the driver board, and the negative terminal pin of the driver MCU connected to the negative terminal of the driver board;
the driver MCU is connected to the output pin of the second LED chip via an input/output pin, enabling the driver MCU to output varying level signals to the second LED chip upon powering on to control its light emission, and to transmit commands to the control MCU to regulate the light emission mode of the first LED chip.

8. The lighting fixture according to claim 7, wherein the driver MCU has a crystal oscillator input pin and a crystal oscillator output pin, and the crystal oscillator input pin and output pin are connected to a crystal oscillator module for timing.

9. The lighting fixture according to claim 7, wherein the driver MCU is connected via input/output pins to an infrared module; upon receiving an infrared signal, the infrared module transmits an electrical signal to the input/output pins of the driver MCU to alter the timing mode within the driver MCU and/or the control waveform output by the driver MCU.

10. A lamp, comprising the lighting component described in claim 1, further comprising a diffuser lampshade and/or a housing.
